(19) United States
(12) Patent Application Publication
(10) Pub. No.: US 2019/0361282 A1
(43) Pub. Date: Nov. 28, 2019

(54) Touch Display Panel, Method for Manufacturing the Same and Display Device

(71) Applicants: Hefei BOE Display Technology Co., Ltd., Hefei (CN); BOE Technology Group Co., Ltd., Beijing (CN)

(72) Inventors: Defu WANG, Beijing (CN); Jiguang Ye, Beijing (CN)

(21) Appl. No.: 16/266,790

(22) Filed: Feb. 4, 2019

(30) Foreign Application Priority Data
May 22, 2018 (CN) 201820764145.2

(51) Int. Cl. G02F 1/1345; G06F 3/041; H01L 27/32; G02F 1/1362

(52) U.S. Cl. CPC G02F 1/13454; G06F 3/0412; G02F 1/1362; H01L 27/3244; H01L 27/323

(57) ABSTRACT

A touch display panel includes first and second substrates opposite to each other, wherein a surface of the first substrate distal to the second substrate is a light exit surface including a display region and a peripheral region; a first driver provided at a first side of the peripheral region; and a second driver provided at a second side of the second substrate, wherein the first and second sides overlap each other in a stacking direction of the first and second substrates. An extension region, along a lengthwise direction of the second side, of an orthographic projection of the first driver on the second substrate is a first extension region, an extension region, along the lengthwise direction, of a region of the second substrate occupied by the second driver is a second extension region, and the first and second extension regions at least partially overlap each other.

### CROSS-REFERENCE TO RELATED APPLICATIONS

The present application claims the priority of Chinese Patent Application No. 201820764145.2, filed on May 22, 2018, the contents of which are incorporated herein in their entirety by reference.

### TECHNICAL FIELD

The present disclosure relates to the field of display technology, and in particular, relates to a touch display panel, a method for manufacturing the same, and a display device.

### BACKGROUND

Touch technology has been widely used in electronic devices such as computers and smart phones. Smart phones provided with the touch technology currently available on the market are mainly classified, according to the combining manner of a panel of each of the smart phones with a touch sensor, into two types, namely, in-cell touch technology and on-cell touch technology. The in-cell touch technology refers to a technology of embedding the touch sensor into a pixel. The On-cell touch technology refers to a technology of providing the touch sensor between a color filter substrate of a liquid crystal display panel and a polarizer, or on a transparent cover of an OLED display panel.

### SUMMARY

Embodiments of the present disclosure provide a touch display panel, a method for manufacturing the same, and a display device.

Some embodiments of the present disclosure provide a touch display panel, which includes

a first substrate and a second substrate arranged opposite to each other, wherein a surface of the first substrate distal to the second substrate is a light exit surface, and the light exit surface includes a display region and a peripheral region, which is a non-display region;

a first driver provided at a first side of the peripheral region of the first substrate; and

a second driver provided at a second side of the second substrate, wherein the first side and the second side overlap each other in a stacking direction of the first substrate and the second substrate;

wherein an extension region, along a lengthwise direction of the second side, of an orthographic projection of the first driver on the second substrate is a first extension region, an extension region, along the lengthwise direction of the second side, of a region of the second substrate occupied by the second driver is a second extension region, and the first extension region and the second extension region at least partially overlap each other.

In an embodiment, the orthographic projection of the first driver on the second substrate does not overlap the second driver, a notch is formed at the first side of the peripheral region of the first substrate, and the notch completely exposes the second driver.

In an embodiment, a shape of the notch includes a substantial rectangle.

In an embodiment, the notch is located at an end, opposite to the first driver, of the first side of the peripheral region of the first substrate.

In an embodiment, the notch includes a first sidewall and a second sidewall connected to each other, and a connection position of the first sidewall and the second sidewall is an arc-shaped corner.

In an embodiment, the touch display panel is an on-cell touch display panel, the first driver is provided on a surface of the first substrate distal to the second substrate, and the second driver is provided on a surface of the second substrate proximal to the first substrate.

In an embodiment, the touch display panel further includes a touch layer and a protection layer sequentially provided on the light exit surface of the first substrate, wherein the protection layer covers both the touch layer and the first driver.

In an embodiment, the first driver includes a touch driver, and the second driver includes a display driver.

In an embodiment, the touch display panel further includes a liquid crystal layer provided between the first substrate and the second substrate.

In an embodiment, the first substrate is a transparent cover, and the second substrate is an OLED display panel.

Some embodiments of the present disclosure provide a display device, which includes the touch display panel according to any one of the embodiments of the present disclosure.

Some embodiments of the present disclosure provide a method for manufacturing a touch display panel, including steps of

forming a first substrate and a second substrate such that the first substrate and the second substrate are arranged opposite to each other, a surface of the first substrate distal to the second substrate being a light exit surface, and the light exit surface including a display region and a peripheral region, which is a non-display region;

arranging a first driver at a first side of the peripheral region of the first substrate; and

arranging a second driver at a second side of the second substrate such that the first side and the second side overlap each other in a stacking direction of the first substrate and the second substrate;

wherein an extension region, along a lengthwise direction of the second side, of an orthographic projection of the first driver on the second substrate is a first extension region, an extension region, along the lengthwise direction of the second side, of a region of the second substrate occupied by the second driver is a second extension region, and the first extension region and the second extension region at least partially overlap each other.

In an embodiment, the orthographic projection of the first driver on the second substrate does not overlap the second driver, and the method further includes a step of

forming a notch at the first side of the peripheral region of the first substrate such that the notch completely exposes the second driver.

In an embodiment, the step of forming a notch includes a step of

forming the notch whose shape includes a substantial rectangle.

In an embodiment, the step of forming the notch whose shape includes a substantial rectangle including a step of

forming the notch at an end, opposite to the first driver, of the first side of the peripheral region of the first substrate.

In an embodiment, the step of forming the notch includes a step of forming a first sidewall and a second sidewall connected to each other, wherein a connection position of the first sidewall and the second sidewall is an arc-shaped corner.

In an embodiment, the touch display panel is an on-cell touch display panel, the first driver is provided on a surface of the first substrate distal to the second substrate, and the second driver is provided on a surface of the second substrate proximal to the first substrate.

In an embodiment, the method further includes a step of

forming a touch layer and a protection layer sequentially on the light exit surface of the first substrate such that the protection layer covers both the touch layer and the first driver.

In an embodiment, the method further includes a step of

filling a liquid crystal layer between the first substrate and the second substrate.

In an embodiment, the method further includes steps of

preparing a transparent cover as the first substrate, and preparing an OLED display panel as the second substrate.

### BRIEF DESCRIPTION OF THE DRAWINGS

FIG. 1 is a schematic side view showing a touch display panel according to an embodiment of the present disclosure;

FIG. 2 is a schematic top view showing a touch display panel according to an embodiment of the present disclosure;

FIG. 3 is a schematic diagram showing a structure of a touch display panel according to an embodiment of the present disclosure;

FIG. 4 is a schematic top view showing the touch display panel shown in FIG. 3;

FIG. 5 is a schematic diagram showing a process for forming a notch by a cutting process according to an embodiment of the present disclosure;

FIG. 6 is a schematic diagram showing another process for forming a notch by a cutting process according to an embodiment of the present disclosure; and

FIG. 7 is a schematic left side view showing the touch display panel shown in FIG. 3.

### DETAILED DESCRIPTION

To enable one of ordinary skill in the art to better understand technical solutions provided by the present disclosure, the present disclosure will be further described in detail below with reference to the accompanying drawings and specific embodiments.

It should be noted that, the terms “first”, “second” and the like used herein do not denote any order, quantity or importance, but are merely used for distinguishing one component from another. For example, a “first component” in one embodiment may be referred to as a “second component” in another embodiment, and vice versa. The term “comprise”, “include” or the like means that an element or object preceding the term contains the listed element or object following the term and an equivalent thereof, without excluding the presence of another element or object.

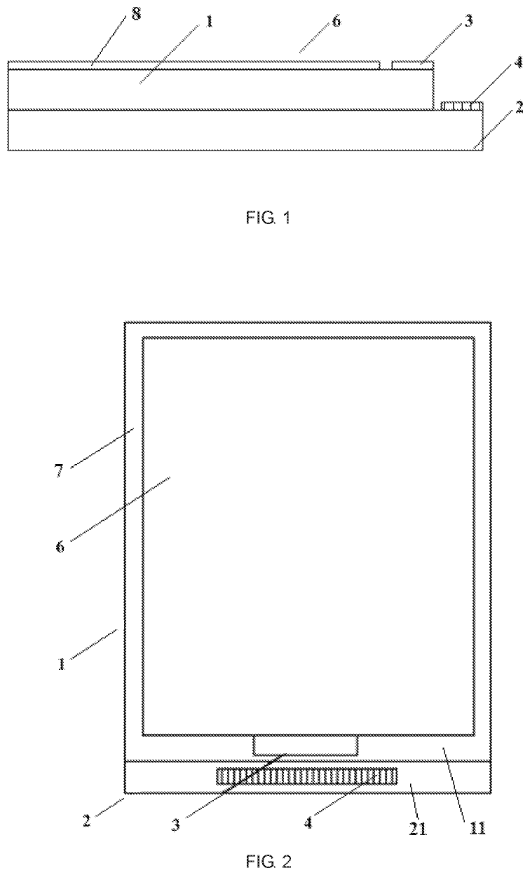

As shown in FIGS. 1 and 2, an embodiment of the present disclosure provides a touch display panel including a first substrate 1 and a second substrate 2 that are arranged opposite to each other. For example, the first substrate 1 and the second substrate 2 may be arranged opposite to each other and substantially aligned with each other in a stacking direction (e.g., the vertical direction in FIG. 1) of the first substrate 1 and the second substrate 2. A surface (e.g., the upper surface in FIGS. 1 and 2) of the first substrate 1 distal to the second substrate 2 is a light exit surface, and the light exit surface includes a display region 6 and a peripheral region 7 which is a non-display region. For example, the peripheral region 7 may surround the display region 6. The touch display panel may further include a first driver 3 provided on a first side 11 of the peripheral region 7 of the first substrate 1. The touch display panel may further include a second driver 4 provided on a second side 21 of the second substrate 2 corresponding to the first side 11 of the peripheral region 7. For example, the second side 21 and the first side 11 overlap each other in the stacking direction of the first substrate 1 and the second substrate 2. In the touch display panel, in order to connect (or bond) the first driver 3 and the second driver 4 to corresponding flexible printed circuit boards, respectively, an orthographic projection of the first driver 3 on the second substrate 2 (e.g. the area occupied by the first driver 3 as shown in FIG. 2) does not overlap the second driver 4. Further, an extension region, along a lengthwise direction (e.g., the horizontal direction in FIG. 2) of the second side 21, of the orthographic projection of the first driver 3 on the second substrate 2 is a first extension region (similar to the region A in FIG. 4), and an extension region, along the lengthwise direction of the second side 21, of a region of the second substrate 2 occupied by the second driver 4 is a second extension region (similar to the region B in FIG. 4). The first extension region and the second extension region do not overlap each other.

In an embodiment, as shown in FIG. 2, each of the first substrate 1 and the second substrate 2 may be a rectangle. The first substrate 1 and the second substrate 2 may have a same width (i.e., a size in the horizontal direction in FIG. 2), and a length (i.e., a size in the vertical direction in FIG. 2) of the first substrate 1 may be smaller than that of the second substrate 2. In other words, an area of the first substrate 1 may be smaller than that of the second substrate 2.

In the touch display panel as shown in FIGS. 1 and 2, a ratio of an area occupied by both the first driver 3 and the second driver 4 to an area (e.g., an area of the second substrate 2) of the entire touch display panel is relatively large, and thus a ratio of an area of the display region 6 to the area of the entire touch display panel is decreased. Therefore, the visual experience effect brought by a display device including the touch display panel to a user is degraded.

Other embodiments of the present disclosure provide a novel touch display panel and a method for manufacturing the same, and a ratio of an area of the display region 6 of the novel touch display panel to an area of the entire novel touch display panel is increased.

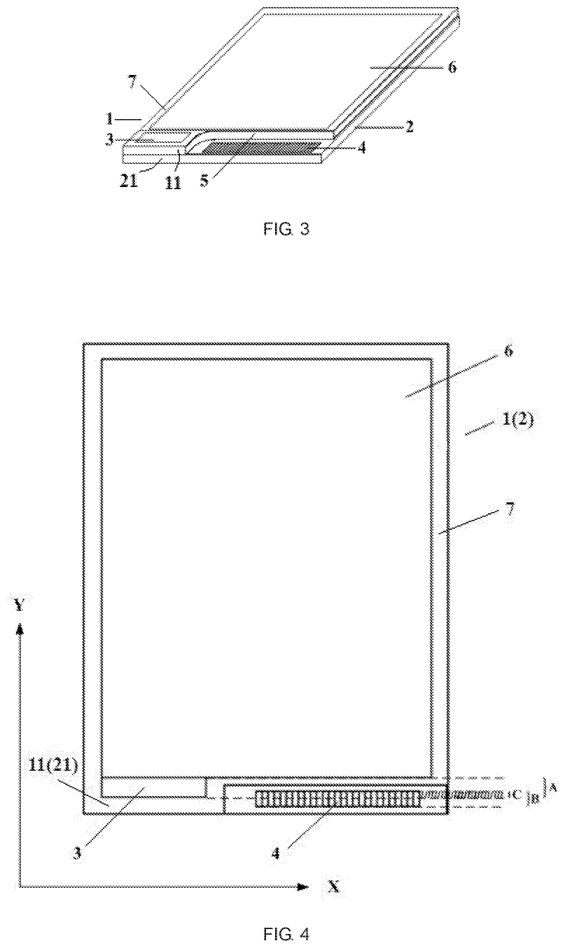

As shown in FIGS. 3 and 4, an embodiment of the present disclosure provides a touch display panel including a first substrate 1 and a second substrate 2. The first substrate 1 and the second substrate 2 are arranged opposite to each other. For example, the first substrate 1 and the second substrate 2 may be arranged opposite to each other and be substantially aligned with each other in the stacking direction of the first substrate 1 and the second substrate 2. A surface of the first substrate 1 distal to the second substrate 2 is a light exit surface (e.g., the upper surface in FIGS. 3 and 4), and the light exit surface includes a display region 6 and a peripheral region 7, which is a non-display region. For example, the peripheral region 7 may surround the display region 6. The touch display panel may further include a first driver 3 provided on a first side 11 of the peripheral region 7 of the first substrate 1. The touch display panel may further include a second driver 4 provided at a second side 21 of the second substrate 2 corresponding to the first side 11 of the peripheral region 7. For example, the second side 21 and the first side 11 overlap each other in the stacking direction of the first substrate 1 and the second substrate 2. In the touch display panel, an extension region, along the lengthwise direction (e.g., the X-axis direction or the horizontal direction in FIG. 4) of the second side 21, of an orthographic projection of the first driver 3 on the second substrate 2 is a first extension region A, and an extension region, along the lengthwise direction of the second side 21, of a region of the second substrate 2 occupied by the second driver 4 is a second extension region B. The first extension region A and the second extension region B at least partially overlap each other, and an overlapping region is, for example, the region C as shown in FIG. 4.

In an embodiment, as shown in FIGS. 3 and 4, each of the first substrate 1 and the second substrate 2 may be a substantial rectangle. The first substrate 1 and the second substrate 2 may have the same width (e.g., the size in the horizontal direction in FIG. 4) and substantially the same length (e.g., the size in the vertical direction in FIG. 4). In other words, an area of the first substrate 1 may be substantially equal to that of the second substrate 2.

As an example, as shown in FIG. 4, in the embodiment, the lowermost portion of the touch display panel is taken as the first side 11 or the second side 21, and an extension direction of the first side 11 or the second side 21 is the positive direction of the X-axis in the Cartesian coordinate system. In addition, description is given by taking the case where the first driver 3 is a touch driver and the second driver 4 is a display driver as an example.

In an embodiment, as shown in FIG. 4, since the first extension region A and the second extension region B at least partially overlap each other in the positive direction of the X-axis, the orthographic projection of the touch driver (i.e., the first driver 3) on the second substrate 2 and the display driver (i.e., the second driver 4) share a certain horizontal region of the touch display panel (e.g., the second substrate 2), and the certain horizontal region may be the region C. It can be seen that, such a configuration can significantly decrease a ratio of an area occupied by both the touch driver and the display driver to an area (e.g., the area of the second substrate 2) of the entire touch display panel, thereby increasing a ratio of an area of the display region 6 to the area of the entire touch display panel. That is, the area of the display region 6 of the touch display panel is increased. Therefore, the visual experience effect brought by a display device including the touch display panel to a user is improved.

In an embodiment, the touch display panel may be a liquid crystal display (LCD) touch panel. In this case, the first substrate 1 may be a color filter substrate, and the second substrate 2 may be an array substrate. In another embodiment, the touch display panel may be an organic light emitting diode (OLED) touch display panel. In this case, the first substrate 1 may be a transparent cover (e.g., a glass cover), and the second substrate 2 may be an OLED display panel. For example, the OLED display panel may include a cathode, an organic light emitting layer, and an anode which are sequentially stacked on each other.

For example, results of related experiments are as follows. After the touch driver and the display driver of a 4.7-inch (104 mm*58 mm) OLED touch display panel are arranged according to the arrangement as described above, a ratio of an area of the display region 6 of the OLED touch display panel to the area of the entire OLED touch display panel is increased by 2%, as compared with a ratio of an area of the display region 6 of a conventional OLED touch display panel to the area of the entire conventional OLED touch display panel. After the touch driver and the display driver of a 5.9-inch (138 mm*57 mm) on-cell liquid crystal touch display panel are arranged according to the arrangement as described above, a ratio of an area of the display region 6 of the on-cell liquid crystal touch display panel to the area of the entire on-cell liquid crystal touch display panel is increased by 1.5%, as compared with a ratio of an area of the display region 6 of a conventional on-cell liquid crystal touch display panel to the area of the entire conventional on-cell liquid crystal touch display panel.

In an embodiment, the display driver (i.e., the second driver 4) and the orthographic projection of the touch driver (i.e., the first driver 3) on the second substrate 2 do not overlap each other. Further, a notch 5 is provided at the first side 11 of the peripheral region 7 of the first substrate 1 such that the notch 5 is located at an end opposite to the first driver 3 and is distal to the display region 6, and the notch 5 completely exposes the second driver 4, as shown in FIG. 4. In this way, the display driver (i.e., the second driver 4) is not covered by the first substrate 1, such that the touch driver (i.e., the first driver 3) and the display driver (i.e., the second driver 4) may be simultaneously bonded to their corresponding flexible printed circuit boards, respectively, by using only one bonding process. Thus, the bonding process is simplified, and the cost for the bonding process is decreased.

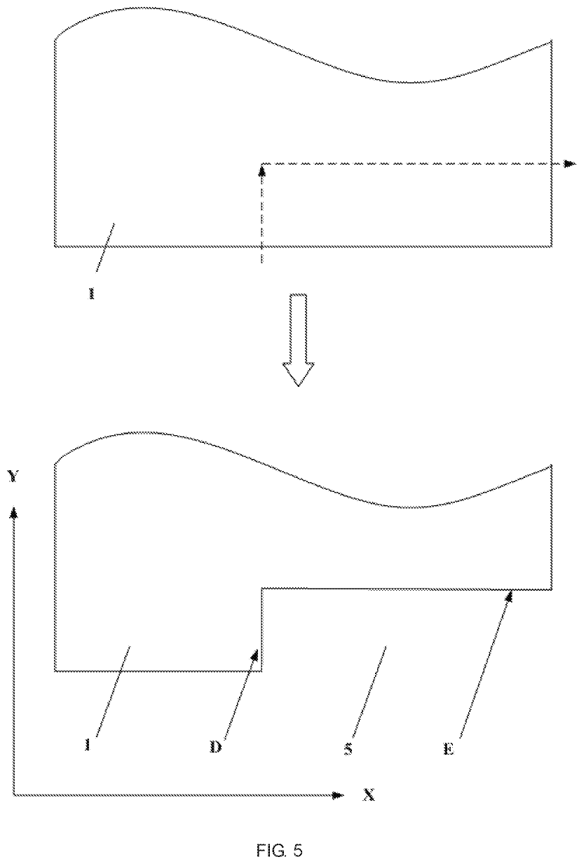

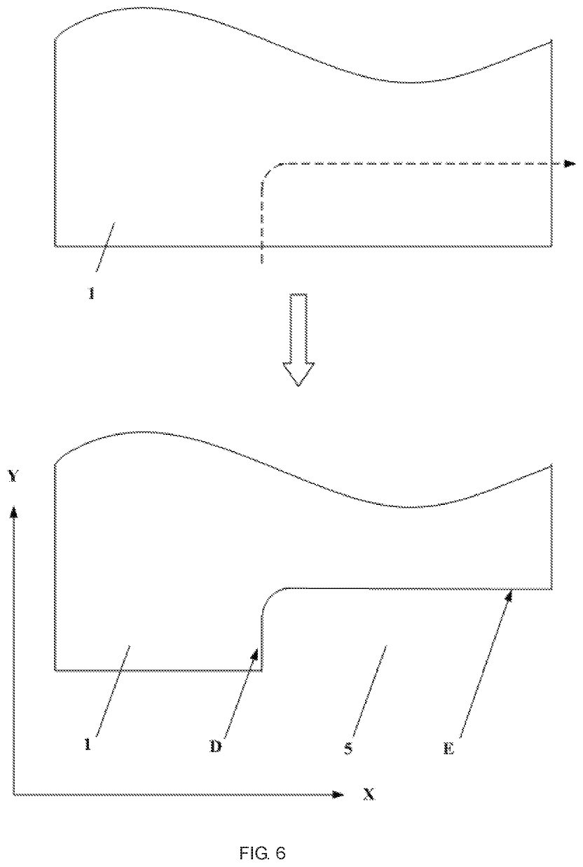

In an embodiment, to make the process of forming the notch 5 on the first substrate 1 simpler, for example, the notch 5 may be formed at an end, opposite to the first driver 3, of the first side 11 of the peripheral region 7 of the first substrate 1. That is, the notch 5 may be formed at the lower right corner of the first substrate 1 as shown in FIG. 4. It can be seen that the overall shape of the notch 5 may be a substantial rectangle. As shown in FIGS. 5 and 6, formation steps of the notch 5 in the shape of a substantial rectangle will be described in detail below.

First, the first substrate 1 may be cut along the positive direction of the Y-axis by a cutter, according to the specific size of the display driver (i.e., the second driver 4). Once the cutting of the first substrate 1 along the positive direction of the Y-axis by the cutter is finished, the cutting direction of the cutter is adjusted without changing the position of the cutter, to cause the cutter to proceed with cutting from that point along the positive direction of the X-axis, such that a substantially rectangular notch 5 is formed. For example, the sidewall obtained by cutting the first substrate 1 along the positive direction of the X-axis using the cutter is a first sidewall E (i.e., the surface E shown in FIG. 5) of the notch 5, and the sidewall obtained by cutting the first substrate 1 along the positive direction of the Y-axis using the cutter is a second sidewall D (i.e., the surface D shown in FIG. 5) of the notch 5.

Alternatively, in the process of forming the substantially rectangular notch 5, the first substrate 1 may be firstly cut along the negative direction of the X-axis, and then the first substrate 1 may be cut along the negative direction of the Y-axis. However, the present disclosure is not limited thereto. For example, the notch 5 according to the embodiment may also be formed by using other suitable processes such as a laser cutting process or the like.

It should be noted that, the first substrate 1 according to the embodiment generally includes a glass substrate, and glass is a brittle material. Thus, in the above two cutting processes of cutting the first substrate 1 along the X-axis direction and the Y-axis direction, respectively, a crack is prone to occur at a connection position of the first sidewall E and the second sidewall D of the notch 5. When the first substrate 1 having a microcrack is subjected to an external stress, the microcrack of the first substrate 1 is easily extended, resulting in breakage of the entire first substrate 1. In this case, the first substrate 1 formed by the above cutting processes can only be discarded as useless. In order to avoid this problem, in an embodiment, the connection position of the first sidewall E and the second sidewall D of the notch 5 may be formed as an arc-shaped corner (or rounded corner). For example, as shown in FIG. 6, a notch 5 having an arc-shaped corner may be formed by using only one cutting process. That is, the connection position of the first sidewall E and the second sidewall D of the notch 5 is formed into the arc-shaped corner, such that not only the preparation process is simplified, but also the first substrate 1 is effectively prevented from cracking during the cutting process. As a result, the yield of the first substrates 1 is increased, and the production cost thereof is decreased.

Hereinafter, in order to make the structure of the touch display panel provided by the present embodiment clearer, further description will be given by taking an on-cell touch display panel as an example.

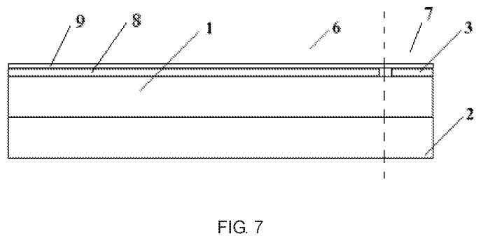

In an embodiment, the touch driver (i.e., the first driver 3) of an on-cell touch display panel is provided on a surface of the first substrate 1 distal to the second substrate 2, and a touch layer 8 is further provided on the surface. For example, the touch layer 8 may be provided in the display region 6, as shown in FIGS. 1 and 7. The display driver (i.e., the second driver 4) is provided on a surface of the second substrate 2 proximal to the first substrate 1. In addition, a liquid crystal layer may be provided between the first substrate 1 and the second substrate 2, i.e., the touch display panel may be a liquid crystal display touch panel. In an embodiment, as described above, the touch display panel may also be an OLED touch display panel. However, the present disclosure is not limited thereto. For example, the touch display panel may also be another display panel having a similar structure.

In an embodiment, to prevent moisture in the air from entering the touch display panel to damage the touch display panel, a protection layer 9 is provided on the surface of the first substrate 1 distal to the second substrate 2 (as shown in FIG. 7), and the protection layer 9 can cover both the touch layer 8 and the touch driver (i.e., the first driver 3). In this way, the touch layer 8 and the touch driver are isolated from the air.

As described above, since the first extension region A and the second extension region B in the present embodiment at least partially overlap each other, a ratio of an area occupied by both the touch driver and the display driver to an area of the entire touch display panel is decreased, correspondingly, a ratio of an area of the display region 6 to the area of the entire touch display panel is increased. That is, the area of the display region 6 of the touch display panel is increased. Therefore, the visual experience effect brought by a display device including the touch display panel to a user is improved. Further, the first substrate 1 in this embodiment further has the substantially rectangular notch 5, and the connection position of the first sidewall E and the second sidewall D of the notch 5 is an arc-shaped corner, thereby avoiding the disadvantage of cracking in the case where the connection position of the first sidewall E and the second sidewall D is not an arc-shaped corner (e.g., is a right angle), thereby avoiding the problem that the entire first substrate 1 may be broken when the notch 5 is subjected to an external stress. As a result, the yield of the first substrates 1 is increased, and the production cost thereof is decreased.

An embodiment of the present disclosure provides a display device, which includes the touch display panel provided by any one of the embodiments of FIGS. 3 to 7.

Since the display device according to the present embodiment includes the touch display panel provided by the present disclosure, the display device has a better display effect.

The display device according to the present embodiment may be any product or component having a display function, such as a mobile phone, a tablet computer, a television, a display, a notebook computer, a digital photo frame, a navigator, and the like.

An embodiment of the present disclosure provides a method for manufacturing a touch display panel. As shown in FIGS. 1 to 7, the method may include the following steps S1 to S7.

Step S1 includes forming a first substrate 1 and a second substrate 2, such that the first substrate 1 and the second substrate 2 are arranged opposite to each other, a surface of the first substrate 1 distal to the second substrate 2 is a light exit surface, and the light exit surface includes a display region 6 and a peripheral region 7 which is a non-display region. For example, the first substrate 1 and the second substrate 2 may be arranged opposite to each other and be aligned with each other in the stacking direction of the first substrate 1 and the second substrate 2. Further, the peripheral region 7 may surround the display region 6.

Step S2 includes arranging a first driver 3 at a first side 11 of the peripheral region 7 of the first substrate 1.

Step S3 includes arranging a second driver 4 at a second side 21 of the second substrate 2 such that the first side 11 and the second side 21 overlap each other in the stacking direction of the first substrate 1 and the second substrate 2. In the method, an extension region, along a lengthwise direction of the second side 21, of an orthographic projection of the first driver 3 on the second substrate 2 is a first extension region A, an extension region, along the lengthwise direction of the second side 21, of a region of the second substrate 2 occupied by the second driver 4 is a second extension region B, and the first extension region A and the second extension region B at least partially overlap each other. For example, an overlapping region is the region C as shown in FIG. 4.

In an embodiment, the orthographic projection of the first driver 3 on the second substrate 2 does not overlap the second driver 4, and the method further includes the following step S4.

Step S4 includes forming a notch 5 at the first side 11 of the peripheral region 7 of the first substrate 1 such that the notch 5 completely exposes the second driver 4.

In an embodiment, step S4 may include the following step S41.

Step S41 includes forming the notch 5 of whose shape includes a substantial rectangle.

In an embodiment, step S41 may include the following step S411.

Step S411 includes forming the notch 5 at an end (e.g., the lower right corner of the first side 11 in FIG. 4) of the first side 11 of the peripheral region 7 of the first substrate 1, wherein the end is opposite to the first driver 3.

In an embodiment, step S411 may include the following step S4111.

Step S4111 includes forming a first sidewall E and a second sidewall D such that the first sidewall E and the second sidewall D are connected to each other, and a connection position of the first sidewall E and the second sidewall D is an arc-shaped corner, as shown in FIG. 6.

In an embodiment, the touch display panel is an on-cell touch display panel, the first driver 3 is provided on a surface of the first substrate 1 distal to the second substrate 2, and the second driver 4 is provided on a surface of the second substrate 2 proximal to the first substrate 1. In this case, the method may further include the following step S5.

Step S5 includes forming a touch layer 8 and a protection layer 9 sequentially on the light exit surface of the first substrate 1 such that the protection layer 9 covers both the touch layer 8 and the first driver 3, as shown in FIG. 7.

In an embodiment, the method may further include the following step S6.

Step S6 includes providing a liquid crystal layer between the first substrate 1 and the second substrate 2.

Alternatively, in an embodiment, the method may further include the following step S7.

Step S7 includes preparing a transparent cover (e.g., a glass cover) as the first substrate 1, and preparing an OLED display panel as the second substrate 2.

In the touch display panel manufactured by the method according to any one of the embodiments of the present disclosure, the display region 6 has an increased area, and thus the visual experience effect brought to a user by a display device including the touch display panel is improved. Further, the connection position of the first sidewall E and the second sidewall D of the notch 5 in the first substrate 1 is an arc-shaped corner, thereby avoiding occurrence of a crack in the first substrate 1. As a result, yield of the first substrates 1 is increased, and the production cost thereof is decreased.

It should be understood that, the above embodiments are only exemplary embodiments for the purpose of explaining the principle of the present disclosure, and the present disclosure is not limited thereto. For one of ordinary skill in the art, various improvements and modifications may be made without departing from the spirit and essence of the present disclosure. These improvements and modifications also fall within the protection scope of the present disclosure.

What is claimed is:

1. A touch display panel, comprising
a first substrate and a second substrate which are arranged opposite to each other, wherein a surface of the first substrate distal to the second substrate is a light exit surface, and the light exit surface comprises a display region and a peripheral region which is a non-display region;
a first driver provided at a first side of the peripheral region of the first substrate; and
a second driver provided at a second side of the second substrate, wherein the first side and the second side overlap each other in a stacking direction of the first substrate and the second substrate;
wherein an extension region, along a lengthwise direction of the second side, of an orthographic projection of the first driver on the second substrate is a first extension region, an extension region, along the lengthwise direction of the second side, of a region of the second substrate occupied by the second driver is a second extension region, and the first extension region and the second extension region at least partially overlap each other.

2. The touch display panel according to claim 1, wherein the orthographic projection of the first driver on the second substrate does not overlap the second driver, a notch is formed at the first side of the peripheral region of the first substrate, and the notch completely exposes the second driver.

3. The touch display panel according to claim 2, wherein a shape of the notch comprises a substantial rectangle.

4. The touch display panel according to claim 3, wherein the notch is located at an end, opposite to the first driver, of the first side of the peripheral region of the first substrate.

5. The touch display panel according to claim 4, wherein the notch comprises a first sidewall and a second sidewall which are connected to each other, and a connection position of the first sidewall and the second sidewall is an arc-shaped corner.

6. The touch display panel according to claim 1, wherein the touch display panel is an on-cell touch display panel, the first driver is provided on a surface of the first substrate distal to the second substrate, and the second driver is provided on a surface of the second substrate proximal to the first substrate.

7. The touch display panel according to claim 6, further comprising
a touch layer and a protection layer sequentially provided on the light exit surface of the first substrate,
wherein the protection layer covers both the touch layer and the first driver.

8. The touch display panel according to claim 1, wherein the first driver comprises a touch driver, and the second driver comprises a display driver.

9. The touch display panel according to claim 1, further comprising
a liquid crystal layer provided between the first substrate and the second substrate.

10. The touch display panel according to claim 1, wherein the first substrate is a transparent cover, and the second substrate is an OLED display panel.

11. A display device, comprising the touch display panel according to claim 1.

12. A method for manufacturing a touch display panel, comprising steps of
forming a first substrate and a second substrate such that the first substrate and the second substrate are arranged opposite to each other, a surface of the first substrate distal to the second substrate being a light exit surface, and the light exit surface comprising a display region and a peripheral region which is a non-display region;
arranging a first driver at a first side of the peripheral region of the first substrate; and
arranging a second driver at a second side of the second substrate such that the first side and the second side overlap each other in a stacking direction of the first substrate and the second substrate;
wherein an extension region, along a lengthwise direction of the second side, of an orthographic projection of the first driver on the second substrate is a first extension region, an extension region, along the lengthwise direction of the second side, of a region of the second substrate occupied by the second driver is a second extension region, and the first extension region and the second extension region at least partially overlap each other.

13. The method according to claim 12, wherein the orthographic projection of the first driver on the second substrate does not overlap the second driver, and the method further comprises a step of
forming a notch at the first side of the peripheral region of the first substrate such that the notch completely exposes the second driver.

14. The method according to claim 13, wherein the step of forming a notch comprises a step of
forming the notch whose shape comprises a substantial rectangle.

15. The method according to claim 14, wherein the step of forming the notch whose shape comprises a substantial rectangle comprising a step of
forming the notch at an end, opposite to the first driver, of the first side of the peripheral region of the first substrate.

16. The method according to claim 15, wherein the step of forming the notch comprises a step of
forming a first sidewall and a second sidewall connected to each other, wherein a connection position of the first sidewall and the second sidewall is an arc-shaped corner.

17. The method according to claim 12, wherein the touch display panel is an on-cell touch display panel, the first driver is provided on a surface of the first substrate distal to the second substrate, and the second driver is provided on a surface of the second substrate proximal to the first substrate.

18. The method according to claim 17, further comprising a step of
forming a touch layer and a protection layer sequentially on the light exit surface of the first substrate such that the protection layer covers both the touch layer and the first driver.

19. The method according to claim 12, further comprising a step of
providing a liquid crystal layer between the first substrate and the second substrate.

20. The method according to claim 12, further comprising steps of
preparing a transparent cover as the first substrate, and preparing an OLED display panel as the second substrate.
